(19) United States
(12) Patent Application Publication
(10) Pub. No.: US 2011/0260163 A1
(43) Pub. Date: Oct. 27, 2011

(54) PERMEABLE DIAPHRAGM PIEZORESISTIVE BASED SENSORS

(75) Inventors: Florian Solzbacher, Salt Lake City, UT (US); Michael Orthner, Salt Lake City, UT (US)

(73) Assignee: University of Utah Research Foundation

(21) Appl. No.: 12/922,445

(22) PCT Filed: Mar. 13, 2009
(86) PCT No.: PCT/US09/37189

§ 371 Date: Dec. 14, 2010

Related U.S. Application Data
(60) Provisional application No. 61/036,159, filed on Mar. 13, 2008.
(60) Provisional application No. 61/119,349, filed on Dec. 2, 2008.

(51) Int. Cl. H01L 29/84; H01L 29/04; H01L 29/66; H01L 29/12

(52) U.S. Cl. 257/53; 257/415; 257/77; 257/49; 257/414; 257/E29.324; 257/E29.068; 257/E29.003; 257/E29.166

(57) ABSTRACT

An improved piezoresistive-based sensor (78) can include a cavity (66) in a substantially solid substrate (68). A reactive agent can optionally be present in the cavity (66). A flexible machined membrane can form a wall of the cavity (66). The flexible machined membrane can include an array of channels (76) configured to permit selective passage of a target material into and out of the cavity. Additionally, the flexible machined membrane can include a piezoresistive features (74) associated with the membrane. The reactive agent included in the cavity (66) can be volumetrically responsive to the presence of the target material or fluid. These sensors can be configured as pressure sensors, chemical sensors, flow sensors, and the like.

### RELATED APPLICATIONS

This application claims the priority of U.S. Provisional Patent Application No. 61/036,159, filed Mar. 13, 2008 and U.S. Provisional Patent Application No. 61/119,349, filed Dec. 2, 2008, which are incorporated herein by reference.

### BACKGROUND OF THE INVENTION

A number of devices, such as sensors, utilize structures including at least one piezoresistive feature to measure mechanical deformation of a membrane. Often these sensors are intricate to manufacture and can require large investments of time and capital. Additionally, forming a sensor to desired sensitivity for certain applications can be a difficult undertaking, particularly where materials and methods may be limited by cost, and potential application (i.e. biological environments). Furthermore, most current sensors rely on silicon membranes which can be difficult to design and couple with selective membranes.

### BRIEF DESCRIPTION OF THE DRAWINGS

FIG. 1 is a perspective view of a substrate of a second material and a deposited thin layer of a first material (situated in a continuous layer across the top of the substrate), in accordance with an embodiment of the present invention.

FIG. 2 is a perspective view of the resulting etched holes in the layer of first material, and formed canals in the second material. For better illustration, the solid portions of the substrate are not illustrated. It is the depth of the canals in the substrate that can be used to define the lower wall of the cavity.

FIG. 3 is a perspective, blown-apart view of a cavity. As shown, the cavity is situated directly underneath the holes of the layer of first material. Such cavity is the result of selective etching through the layer of first material.

FIG. 4 is a micrograph of a sensor formed having a stress-reduction pattern of holes across the membrane in accordance with one embodiment of the present invention.

FIG. 5 is a side cross-sectional view of a portion of a sensor made using a front-side approach in accordance with one embodiment of the present invention.

FIG. 6 is a perspective view of a substrate having been etched to form a cavity via a back-side approach followed by drilling of a plurality of holes in a grid pattern in accordance with another embodiment of the present invention.

FIG. 7 is a perspective cross-sectional view of a back-side produced sensor cavity in accordance with one embodiment of the present invention.

FIG. 8 is a side cross-sectional view of a portion of a sensor made using a back-side approach in accordance with one embodiment of the present invention.

FIG. 9 is a perspective view of an array of four sensors made using a back-side approach in accordance with one embodiment of the present invention.

FIG. 10 is a perspective blown-apart view of a sensor device which incorporates the array of FIG. 9.

FIG. 11 is a graph of sensitivity (V/kPa at 5V) versus hole size for three different membrane widths in accordance with one embodiment of the present invention.

These figures are provided merely for convenience such that deviations in shape, size, proportions, and configuration can be made without departing from the scope of the invention.

### DETAILED DESCRIPTION

Reference will now be made to exemplary embodiments, and specific language will be used herein to describe the same. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

Definitions

In describing and claiming the present invention, the following terminology will be used in accordance with the definitions set forth below. It will nevertheless be understood that no limitation of the scope of the invention is thereby intended.

Alterations and further modifications of the inventive features illustrated herein, and additional applications of the principles of the inventions as illustrated herein, which would occur to one skilled in the relevant art and having possession of this disclosure, are to be considered within the scope of the invention.

It must be noted that, as used in this specification and the appended claims, the singular forms “a,” “an,” and “the” include plural referents unless the context clearly dictates otherwise. Thus, for example, reference to “a layer” includes one or more of such layers and reference to “a sealing step” includes reference to one or more of such steps.

As used herein, the term “equidistant pattern” refers to a pattern of hole placement wherein each hole is situated substantially equal distance from the nearest holes, as measured from the center of each hole. Such patterns can be offset or aligned in rows and columns, for example.

As used herein, “machined” refers to any man, computer, or robotic-controlled alteration of a solid material. As such, “machined” includes etching, laser, mechanical, or any other manufactured holes of any shape and size.

As used herein, “two-dimensional array” and “array” synonymously refer to an arrangement which includes multiple features along each of two orthogonal axes. Generally, such arrays will be a patterned design based on desired stresses within the membrane as discussed in more detail herein, although random patterns can also be used.

As used herein, “substantial” when used in reference to a quantity or amount of a material, or a specific characteristic thereof, refers to an amount that is sufficient to provide an effect that the material or characteristic was intended to provide. The exact degree of deviation allowable may in some cases depend on the specific context. Similarly, “substantially free of” or the like refers to the lack of an identified material, characteristic, element, or agent in a composition. Particularly, elements that are identified as being “substantially free of” are either completely absent from the composition, or are included only in amounts that are small enough so as to have no measurable effect on the composition.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, thicknesses, parameters, volumes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc. This same principle applies to ranges reciting only one numerical value. Furthermore, such an interpretation should apply regardless of the breadth of the range or the characteristics being described.

Invention

An improved piezo-based sensor can include a cavity in a substantially solid substrate. An optional reactive agent can be present in the cavity. A flexible machined membrane can form a wall of the cavity. The flexible machined membrane can include an array of channels or holes configured to permit selective passage of a target material into and out of the cavity. Additionally, the flexible machined membrane can include a piezoresistive responsive feature associated with the membrane. The reactive agent included in the cavity can be volumetrically responsive to a presence of the target material. Several different approaches can be suitable in making such sensors and are discussed below. Each approach can also affect the mechanical properties of the sensor devices.

Front-Side Approach

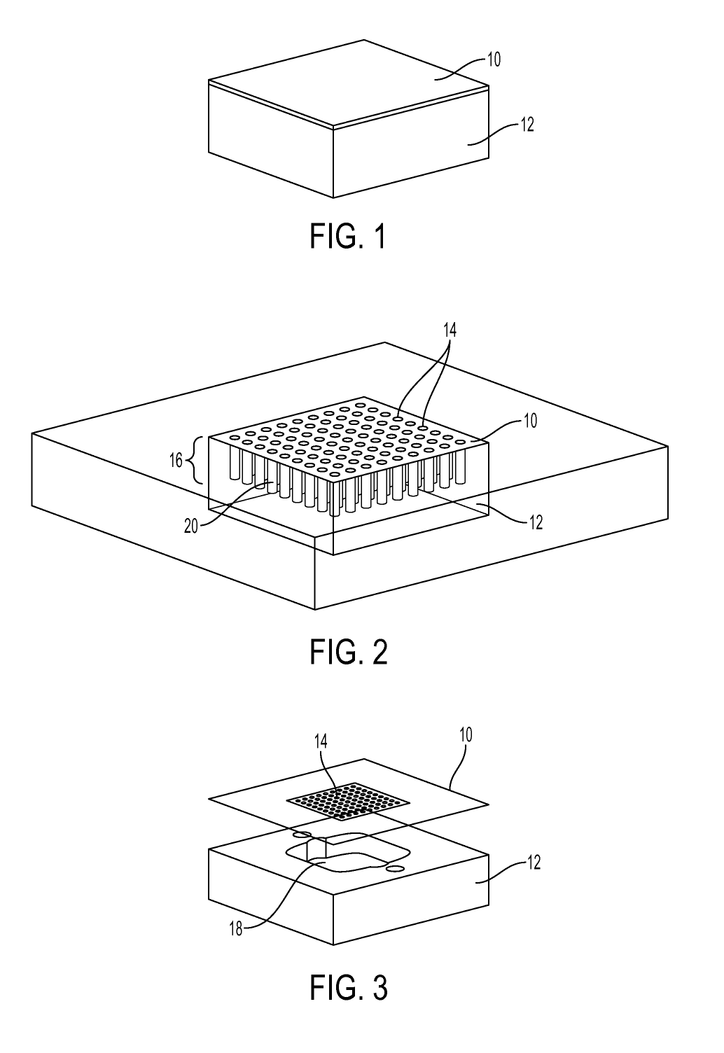

In one approach of the present invention, a front-side method can be used in forming an embedded cavity for a sensor design. Referring to FIG. 1, a first material layer 10 can be attached or formed on a substrate 12 composed of a second material. A plurality of holes can be formed in the first material either before or after attachment to the substrate. FIG. 2 illustrates an approach where holes 14 are drilled through the first material layer 10 and into the substrate 12 to a predetermined depth 16. A cavity can be formed by selectively etching the second material through the holes of the first material. FIG. 3 shows a cavity 18 in the substrate material such that the plurality of holes in the first material 10 form a flexible membrane and simultaneously provide a passageway for materials into and out of the cavity. The cavity formation can generally be accomplished by choosing the first and second materials relative to a particular etchant so as to reduce or substantially eliminate etching of the first material while allowing etching to progress on exposed areas of the second material. As etching proceeds, exposed portions of the substrate are etched and eventually grow together to form a common cavity. As such, the common cavity can be formed which is fluidly connected to the plurality of holes of the first material.

The holes in the first material can be in any suitable random or non-random configuration, provided they are sufficient to provide for the selective etching of a common cavity in the second material. In one aspect, the plurality of holes in the first material can be patterned holes. The pattern can be of any sort, such as, but not limited to, equidistant pattern, concentrated pattern or patterns wherein certain areas of the first material have a greater number of holes than others, off-set pattern, or any combination thereof. Optionally, the holes of the membrane can be patterned in a manner so as to increase sensitivity of the piezoresistive responsive feature or features of the diaphragm. As a non-limiting example, a plurality of piezoresistive responsive features can be adhered or otherwise deposited onto/into the surface of the sensor and the plurality of holes can be concentrated around the plurality of piezoresistive responsive features. Such pattern of holes can be configured, and therefore located and spaced, to increase stress concentration near the piezoresistive responsive features.

The holes in the first material can be of any size or shape. Selection of size and other hole parameters is generally application specific. The size of the holes can be useful in permitting fluid components passage based on size selectivity. In one aspect, in order to allow the highest transportation rate into the cavity, the holes can have the largest allowable diameter without compromising the mechanical integrity of the layer of first material. Besides filtering fluid components based on size, the size of the holes in the membrane can be configured to substantially restrict any migration of the reactive agent through the membrane. Thus, where no other means of exit from the cavity exists, the reactive agent is substantially retained in the cavity. Furthermore, the size and location of the holes can be adjusted to selectively change mechanical stresses across the membrane and resulting output signal. This can be particularly useful in optimizing responses of piezoresistive features located on or in the membrane. In one embodiment, the channels can be sub-micron to several hundred microns in diameter depending on anticipated application.

Further, the shape of the hole can be useful in restricting passage to fluid components capable of passing through the particular hole shape. A variety of hole shapes can be used so as to provide additional selectivity based on fluid component shape. Cracks in structures often initiate and propagate from the locations with high stress and/or strain concentrations. Reducing theses stress and strain concentrations are important structural details to prevent crack initiation and growth. Round holes in thin structural components will create less stress and/or strain in structures than shapes with sharp corners such as hexagons or squares. For this reason, many embodiments include or are comprised essentially of only round holes, although other shapes could be used. As a general guideline, circular holes of about 10 μm to about 40 μm have provided useful results. However, holes ranging in size from several hundred nm to several millimeters can also be suitable for particular applications. Hole spacing can generally be in these same ranges.

The depth of and size of the holes can be utilized to control the diffusion of material into or out of the cavity, and likewise, can affect the noise associated with piezo measurements. Generally, longer or deeper holes can reduce the noise associated with measurement. It may be useful to planarize the membrane material prior to machining holes. In such cases, any method used to planarize a material can be utilized, including but not limited to chemical mechanical planarizing (CMP).

The number of holes and hole size can affect the amount of fluid components permitted passage into and/or out of the cavity. The pitch or angle of the holes can be configured to act as an additional method of restricting access to the cavity. If the density or number of holes is too large then the mechanical strength of the diaphragm is compromised. If too few holes are included, then a desired component of a fluid may not diffuse quickly into the cavity, slowing response time. There are number of tradeoffs that are to be considered regarding the above mentioned parameters for any particular application. Furthermore, the pattern of holes, their size and shape can determine the resulting cavity shape and/or permeable diaphragm properties.

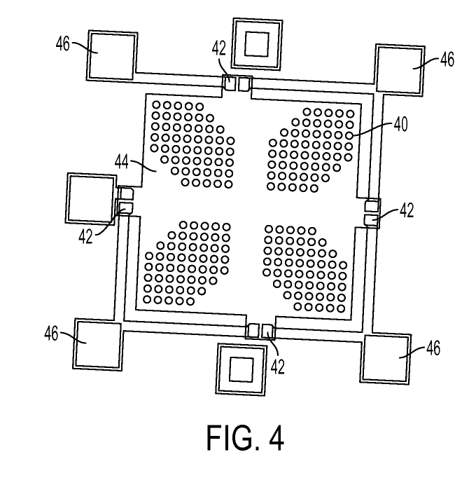

The holes of the first material can also be patterned in a manner so as to increase sensitivity of the piezoresistive responsive feature or features. As a non-limiting example, a plurality of piezoresistive responsive features can be adhered or otherwise deposited onto the surface of the first material and the plurality of holes can be concentrated around the plurality of piezoresistive responsive features. Such pattern of holes can be configured to increase stress concentration near the piezoresistive responsive features. FIG. 4 shows one exemplary design where no holes are placed along central horizontal or vertical axes, e.g. forming a maltese cross pattern of non-perforated membrane. In this design, the holes 40 are oriented in corner regions with the piezoresistive elements 42 being oriented midway along edges of the membrane 44. Electrical contact pads 46 are also provided to allow piezoresistive responses to be measured and correlated with movement of the membrane. At least one piezoresistive responsive feature can be formed in association with the membrane layer. These piezoresistive features can be formed before or after forming the holes and/or the cavity. Such piezoresistive responsive features can be associated with the first material in a variety of ways. Non-limiting examples include direct attachment of a pre-formed piezoresistive responsive feature to a surface of the first material, depositing a piezoresistive material on the first material to form a piezoresistive feature, using the first material as the piezoresistive material, depositing, implanting, impregnating or otherwise chemically growing a layer or distinctive portions of a piezoresistive material on the first layer and combinations thereof. Piezoresistive responsive features can be formed of any piezoresistive material, as would be identified by one of ordinary skill in the materials art.

Along with the piezoresistive responsive features or features, associated leads and circuitry can be attached to allow for communication, application, and/or recordation of electric signals from the piezoresistive elements. The number of piezoresistive responsive features associated with a first material can vary as desired, and such variation is generally related to anticipated use. For example, piezoresistive elements can be oriented along edges of the plurality of channels, at corners of the flexible membrane, and/or distributed across the membrane. In one aspect, when utilizing a piezoresistive responsive feature, it can be useful for the first material to have a Young's Modulus higher than that of the substrate, although this is not required. Non-limiting examples of piezoresistive responsive features include germanium, polycrystalline silicon, amorphous silicon, silicon carbide, and single crystal silicon, diamond and other piezoresistive semiconductors, and combinations of these materials. Currently, piezoresistive elements which are implanted and doped into the substrate are preferred. For example, boron can be implanted at 80 keV giving a dose of 5.5E14 atoms/cm² to a depth of about ˜2 μm. Such integral piezoresistive features not only require less processing than deposited piezoresistive layers, but can avoid substantially changing the flexibility and responses of the membrane. It is also much easier to define very small resistors in very high stress regions. There are also no interfacial surface stresses present when the diaphragm deforms as in the case with an external piezoresistor. This makes the sensor more robust and reliable.

Referring back to FIG. 1, any suitable attachment of a first material layer 10 onto the substrate 12 can be used. Such can be done to any thickness desired, as long as the thickness does not interfere with selective etching of the second material, e.g. undesirable etching effects on the membrane can result from extended etching times. Furthermore, the thickness of the membrane can allow sufficient flexibility to allow functioning of the piezoresistive elements. In one aspect, the layer thickness of the membrane material can be from about 0.01 micron to about 1.5 mm such as about 0.1 micron to about 1 mm. In a further aspect, the thickness of the layer can range from about 3 microns to about 200 microns. The first membrane material layer can be attached using any suitable technique such as, but not limited to, chemical vapor deposition, sputtering, fusion bonding, glass frit adhesion, brazing, gluing, hot pressing, or the like. Deposition processes can be effective for thin layers and are suitable for scale-up.

The step of forming the plurality of holes in the first material can occur prior to the step of attaching the first material on the substrate, or can occur after the step of attaching the first material on the substrate. A variety of methods are useful in the formation of holes. Non-limiting examples of methods of forming a plurality of holes in a layer of the first material include laser ablation, dry etching, DRIE, wet etching, three-dimensional printing, drilling, or combinations thereof. Once holes are formed in the first material, the layer of first material can be attached by any method available. Non-limiting examples include attachment using chemical bonding, fusion bonding, an adhesive, glass frit bonding, and/or mechanically holding the layer in place with a substantially permanent mechanical locking mechanism.

Alternatively, the step of forming holes in the first material can occur subsequent to the step of attaching the first material on the substrate. In such case, the first material can optionally be deposited via chemical means, such as chemical vapor deposition (CVD), or other deposition methods. Still, the layer can be formed separate from the substrate and attached to the substrate prior to hole formation. The first material, prior to hole formation, can be formed in a substantially solid layer, or can include any level of porosity that permits the layer having holes to facilitate selective etching of the second material as desired. In one aspect, it the first material can be substantially solid or include voids in the material that are small enough or situated in such a way so as to provide insufficient fluid connectivity from one side of the layer through the layer to the other side of the layer. In such case, the holes, patterned or otherwise, can form the primary and only fluid routes through the first material.

Where holes are formed in the first material after the first material has been attached to the substrate, the step of forming a plurality of holes in the first material can optionally form a plurality of canals in the second material as illustrated in FIG. 2. The plurality of canals 20 directly correspond to the plurality of holes 14, and are an extension of the formed holes. Canals can be formed in the second material when, e.g., the first material is being chemically etched while attached to the second material. Non-limiting examples of useful etching for such step include reactive ion etching (RIB), deep reactive ion etching (DRIE), dry etching (e.g. xylene etching), isotropic and nonisotropic wet etching, and combinations thereof. DRIB is particularly suitable to produce high aspect ratio canals (e.g. 1:50) of up several mm in depth. This also allows for a high degree of control over the resulting internal contours of the cavity. The depth of canals formed can be altered or controlled through closely monitoring production techniques, particularly selection of etchant in connection with the first and second materials, and time allotted for etching. In one aspect, the depth of the canals in the second material substantially defines a depth of the cavity. In such case, the selective etching serves to merge the formed canals into a common cavity.

Etching holes in the first material, and optionally canals in the second material, can be performed using materials and under conditions that would be apparent to one skilled in the art. Non-limiting examples of masks that can be utilized include nitrides, oxides, metals, photoresists, non-limiting examples of ions that can be utilized for ion etching, if such method is utilized, include nitrogen, H₂, CH₄, CF₄, O₂, SF₆, CHF₃, Ar, chlorine, boron trichloride, and combinations thereof Etching can occur in a vacuum or other pressurized or non-pressurized system. Etching can occur in one or multiple stages, and/or can be combined with other machining. In one aspect, isotrophic etching can include an etchant selected from hydrofluoric, phosphoric, HNA, and/or nitric acids as etchants. Anisotropic wet etchants such as KOH, TMAH, etc can also be used. Once a first material having holes is attached to the substrate, selective etching can be performed to etch or remove portions of the second material sufficient to form a common cavity 18 as illustrated in FIG. 3. Such selective etching relies on an etchant and conditions that allow the etchant to travel through the holes of the first material without greatly or substantially altering the holes of the first material, and effectively etching the second material. As such, the etchant and/or conditions of etching must have a greater selectivity for the second material over the first material so as to allow etched areas to progressively unite to form a common cavity. In one aspect, the etchant has a selectivity for the second material over the first material of greater than about 10:1.

The materials utilized as first and second materials can vary greatly and can independently be selected from ceramics, semiconductors, metals, polymers, and combinations or mixtures thereof. Further, the materials utilized as first and second materials can comprise or consist essentially, and can be selected independently, of porous or substantially solid materials. The material of the membrane can often be capable of machining and can be flexible enough to allow function of the piezoresistive features. Non-limiting examples of ceramics include aluminas, zireonias, carbides, borides, nitrides, silicides, and composites thereof. Non-limiting examples of metals include nickel, chrome, aluminum, titanium, gold, platinum, and alloys, composites or combinations thereof. Further, additives can be included in either or both of the first and second material. Such additives can aid in processing, alter the final composition properties, etc. Preferably, the first and second materials are selected so as to properly coordinate and thus facilitate selective etching. In one embodiment, the first material can comprise or consist essentially of SiC, and the second material can comprise or consist essentially of Si. Various forms of SiC can be utilized, such as, for example, cubic SiC and nitrogen-doped SiC. Generally, the membrane material can be formed of any suitable material. A semi-conducting material can be used when forming piezoresistive features embedded in or integral with the membrane. Alternatively, a dielectric material can be used if the piezoresistive elements are formed on top of the membrane layer. Non-limiting examples of currently preferred membrane materials include silicon carbide, silicon nitride, silicon oxide, composites thereof, and combinations thereof.

The selective etching effectively forms a cavity-containing structure. Such structure includes a first material attached in a layer on a substrate of a second material, where the first material includes a plurality of channels. The cavity is substantially enclosed by the first material and the second material. Due to the method of formation, the cavity is in fluid communication with the plurality of channels of the first material. Optionally, a piezoresistive responsive feature can be associated with the first material, as discussed previously. Additionally, the channels can optionally be in a pattern, and can further be configured to increase sensitivity of the piezoresistive responsive feature, if present.

In one aspect, the channels of the membrane layer can be configured to function as a size-restrictive filter. Thus, inclusion of the cavity-containing structure in an appropriate fluid would necessarily permit passage of a select portion of the fluid having a smaller size into and out of the cavity, while restricting passage to the remaining components of the fluid which have a larger size.

Creating a pressure sensor having a membrane with channels incorporated can be complex. If the density of channels is too large then the mechanical strength of the membrane is compromised. If too few channels are included then the target material in solution will not diffuse quickly into the hydrogel or other reactive agent, thus slowing response time. The channel size plays a primary role in the diffusion of target material into the hydrogel cavity. This diffusion allows the hydrogel to react with target material causing swelling. Generally, the hydrogels do not need semi-permeable membranes in order to function properly since the hydrogels themselves are selective to particular analytes. Therefore, the channel size does not need to be so small it is used for selective physiological permeation. In order to allow the highest diffusion rate into the cavity, the channels will have the largest allowable diameter without compromising the mechanical integrity of the diaphragm.

The cavity-containing sensors can have application in biological environments. In one aspect, a cavity-containing structure can be utilized as a biological sensor for use inside a human body. In such case, and similar cases, the cavity containing structure can be formed of materials that are compatible with biological environments. Alternatively, or in addition, the cavity-containing structure can be coated with a material that increases resistance to biological degradation. Additionally, or alternatively, the materials utilized as the first and/or second materials can be selected to be compatible with biological environments. Such compatibility can include consideration of resistance to degradation or chemical alteration, as well as potential to cause negative toxicological effects in the proposed biological environment.

The cavity can be used to hold or contain materials, provided the bulk of the material is not of a size and/or shape, etc., that can cross in bulk through the holes of the layer of first material. A reactive agent can be present in the cavity and can be introduced by injecting via a suitably large conduit or otherwise encased within the cavity by placement therein and subsequent bonding of a backing substrate. Any injection conduit can subsequently be plugged or sealed using epoxy or other suitable material. The reactive agent is volumetrically responsive to a presence of a target material. In context of the present invention, target material is understood to include reference to target light. The membrane can be configured to permit passage of a target material into the cavity, wherein it can cause a reaction or otherwise be absorbed by the reactive agent. Such reaction or absorbance can cause the reactive agent to swell. Where the substrate material is substantially solid, and the membrane is flexible, the majority of the force of the swelling or increase in volume, will work to flex the membrane. Such flexing will be measurable by the piezoresistive responsive feature or features. Thus, in one aspect, the reactive agent can be configured to produce a force against the flexible membrane upon the presence of the target material. In one embodiment, the reactive agent can be volumetrically responsive to absorption of the target material. Although a variety of target materials or light having specified wavelengths can be measured, in one specific aspect, the target material can be glucose. The reactive agent can also be other absorbent material. Creating the holes in the first material does not require the hydrogels to be held in place using meshing of other means.

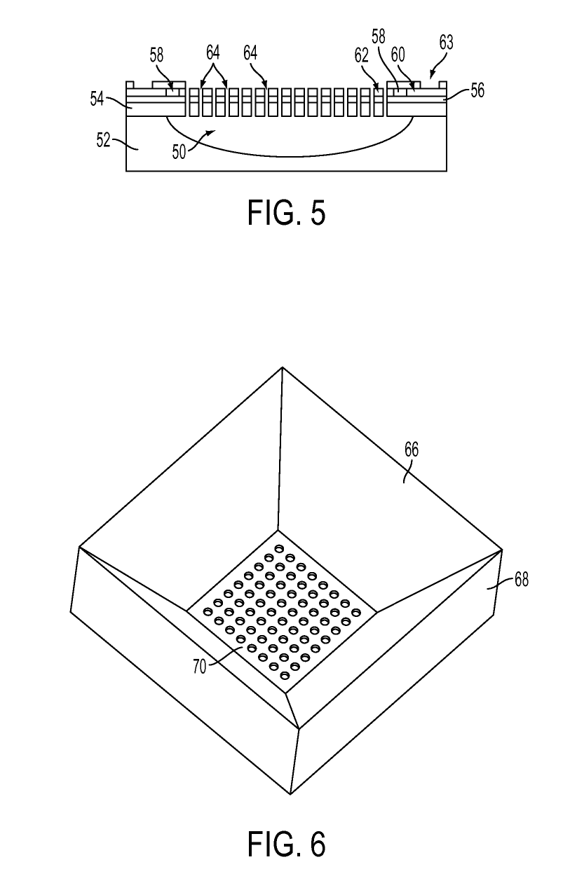

FIG. 5 illustrates a side view of a front-side embodiment of the present invention including piezoresistive elements and an associated metallization scheme. This approach can include a ten step fabrication process including substantially only front-side processing. In this design, the cavity 50 is present in the silicon substrate 52 with a silicon carbide membrane 54. An LPCVD nitride layer 56 functions as a spacing layer between the membrane and the piezoresistive features 58. Metal interconnects 60 can also be provided adjacent the piezoresistive features. A silicon nitride passivation layer 62 can be provided to isolate materials from oxidation and exposure and leave open pads 63 for electrical connections. In this design, the holes 64 provide fluid communication between external environment and the cavity.

Many design and process options can be utilized to improve various aspects of the device and/or methods. Incorporation of permeation holes, particularly patterned ones, into the layer of first material can be used to produce areas with higher stress concentrations than if it was solid (assuming the same width and thickness). This allows for a higher sensitivity in using piezoresistive responsive features. Additionally, the size, shape, location, number, and pitch of the holes can be controlled to directly affect the allowance of movement from through the layer of first material, and thus access into and out of the cavity. This modification enables the manipulation of selectivity and response time when configured as a sensor. Further, the fabrication process is simplified, reducing the total manufacturing cost of the devices.

Back-Side Approach

Although the front-side approach described above can be desirable, a back-side approach can also be suitable for some embodiments. Most of the principles, materials and configurations discussed in connection with either the front-side approach or the back-side approach can be applied to either approach.

In one aspect of the present invention, a sensor can include a cavity having at least one perforated membrane wall. A piezoresistive system can be mechanically associated with the perforated membrane wall such that flexure of the perforated membrane changes a resistance of the piezoresistive system. A conductive pad can also be electrically associated with the piezoresistive system. The cavity can be either substantially enclosed or open to a fluid. Typically, there is only one perforated membrane wall although multiple perforated membranes could be used.

The perforated membrane wall includes a plurality of holes which are oriented in a non-random predetermined pattern. The perforated membrane is intended to mean any membrane which has intentionally produced holes formed therein subsequent to formation of the membrane material. For example, the material may be a permeable or semi-permeable material but additional holes are formed therein as described in more detail herein. However, the pattern can be optimized through consideration of membrane strength, sensitivity, selectivity for certain species, and the like. Thus, in one specific embodiment, the plurality of holes can be configured to increase sensitivity of the piezoresistive system.

The sensor can be formed using substantially only front-side processing as described in connection with FIGS. 1-3. This approach has the benefit of using conventional CMOS processing and can be relatively efficient requiring minimal retooling. However, the sensor can also be formed using a combination of back and front-side processing. Referring to FIG. 6, a cavity 66 can be formed in a substrate 68 such that the cavity includes at least one membrane wall 70. For example, the cavity can be formed by etching the substrate to form a cavity and leaving only enough material along a thickness of the substrate sufficient to form the membrane wall having a predetermined membrane thickness. This can be readily accomplished using conventional wet etching techniques, e.g. KOH etching. In one aspect, the cavity is formed by anisotropic etching of a <100> plane of the substrate such that side walls form substantially along <111> planes. This is illustrated in FIG. 6 as the side walls are inclined along the <111> plane of silicon, i.e. the <100> plane of silicon is typically the exposed surface of most commercial silicon wafers. Portions of the substrate back-side can be masked, e.g. using PE or LPCVD nitride or the like, to form one or more windows through which the cavities can be etched.

Although the plurality of holes can be formed in the membrane wall as previously discussed after formation of the cavity, one approach is to first form the holes on a front-side of the substrate and then to fill those holes with an etch stop, e.g. nitride or wax. The etching can then be performed for a sufficient time to create the cavity and leave the desired thickness. As such the cavity side walls and membrane are formed of a single continuous material. A suitable backing substrate such as a glass or silicon backing wafer can be bonded to the backside of the sensor. Such a backing substrate can include optional hydrogel filling channels to allow introduction of hydrogel into the cavity. Such channels can plugged after the hydrogel has filled the cavity.

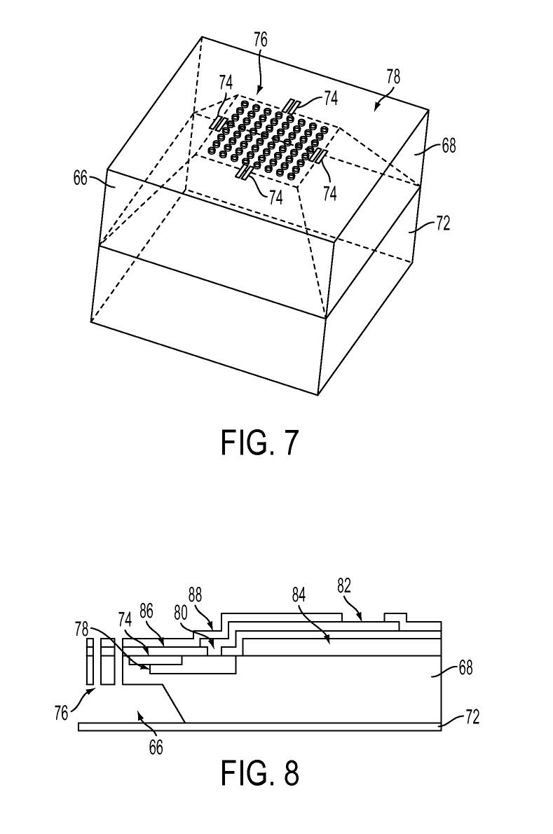

FIG. 7 shows a perspective cross-sectional view of a back-side produced sensor. In this design, the cavity 66 in the substrate 68 is enclosed by backing substrate 72. Piezoresistive elements 74 are oriented along edges of the array of holes 76 along the top surface 78 of the sensor.

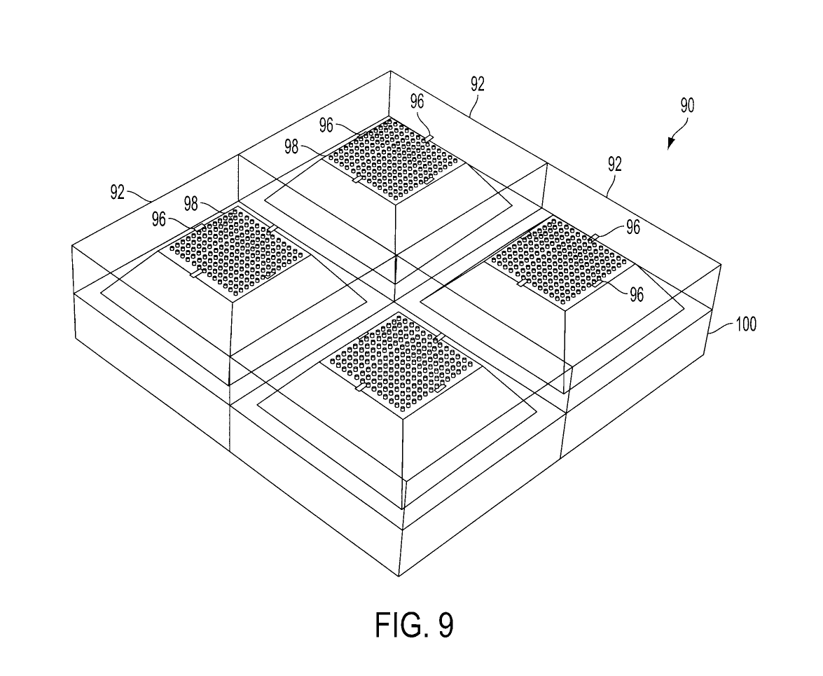

FIG. 8 illustrates a partial side view of a piezoresistive system being associated with the membrane wall and metal contacts of a back-side produced sensor. This metallization design shows the substrate 68 with a cavity 66 backed by backing substrate 66. Piezoresistive elements 74 are implanted into the subsrtrate near the periphery of the array of holes 76. A semi-conducting P-doped region 78 allows for electrical connection with metal contacts 80 which include exposed contact pads 82. The active layer 84 opens the thicker oxide over the diaphragm region for ion implantation and provides a dielectric layer the metallization is placed on top of. A thermal oxide layer 86 provides a defined region for the metallization to contact the piezoresistors and acts as passivation. A passivation layer 88 (e.g. Si₃N₄) can overlay the entire structure, except contact pads. The scheme shown can involve a fourteen step fabrication process.

A wide variety of materials can be suitable for use as the substrate. Although silicon is currently preferred, other materials can be generally used such as, but not limited to, semiconductors, ceramics, polymers, and combinations and mixtures thereof. Suitable substrate materials can be mechanically sound, substantially non-reactive in the intended environment, and capable of being formed into the desired shapes. This metallization process can be applied to either the front-side approach or the back-side approach for forming the cavities.

The cavity can optionally be substantially filled with a hydrogel. Hydrogels can be specifically chosen to selectively absorb a target species such as glucose. Non-limiting examples of suitable hydrogels can include polyelectrolyte hydrogels, substituted acrylic or acrylamide copolymers, acrylic or acrylamide copolymers, PVA/PAA, NIPAAm(N-isopropylacrylamide)-DMIAAm (2-dimethyl maleinimido-N-ethyl-acrylamide chromophor)-DMAAm(dimethylacrylamide) copolymers (e.g. 2-vinylpyridine block/NIPAAm-DMIAAm copolymer, 4-vinylpyridine block/NIPAAm-DMIAArn copolymer, 66.3% NIPAAm-30.7% DMAAm-3% DMIAAm copolymer), and combinations thereof Although not required, the hydrogels can be optionally pre-conditioned. Other suitable hydrogel materials can include materials synthesized by free radical cross-linking copolymerization of hydroxypropyl methacrylate (HPMA, Polysciences, Inc.), (N,N-dimethylamino)ethyl methacrylate (DMA, Polysciences, Inc.) and cross-linker tetraethylene glycol dimethacrylate (TEGDMA, Polysciences, Inc.).

Furthermore, some hydrogels appear to perform with higher sensitivity when they are prestressed. Specifically, the hydrogels can be confined within the cavity leaving substantially no space. In some cases, the hydrogels can be oriented in the cavity so as to produce a slight initial pressure against the membrane prior to exposure to the desired target material. This can be accomplished, for example, by over-filling the cavity. Although specific performance can depend on the hydrogel chosen and the particular configuration, hydrogel swelling for smart hydrogels can be reversible. Furthermore, pH responses tend to be reversible and slower than ionic strength changes.

The hydrogel and the perforated membrane in combination can be configured to be selectively permeable to at least one of glucose, CO₂, and hydrogen ion (pH detection). In one specific embodiment of the present invention, the perforated membrane is part of a Severinghaus membrane for CO₂ detection.

The perforated membrane can have four edges and the piezoresistive system comprises four piezoresistive elements, each oriented along one of the four edges. Regardless of the specific design, the sensors of the present invention allow migration of a target species across the membrane which flexes as a result of changes in volume of the hydrogel. Thus, in these embodiments, the perforated membrane can be the primary or substantially only route for target species to enter the cavity. The sensors of the present invention can be suitable for a variety of applications such as, but not limited to, pressure sensors, chemical sensors, flow sensors, and the like.

A sensor array can also be formed using the sensors of the present invention. FIG. 9 illustrates one example of an array 90 of four sensors 92 formed using a back-side process. Each sensor has an array of channels 94 with four piezoresistive elements 96 implanted in the membrane 98. Such an array can include multiple dedicated sensors which can each be configured to detect a particular species, e.g. glucose, CO₂, pH, and/or act as a reference. The reference can be a hydrogel without any analyte-specific interactions and is used to remove any nonspecific response of the sensor. A typical array can utilize a common substrate 100 into which each of the four sensors is embedded. The sensors can be formed simultaneously in the same manner as described for a single sensor.

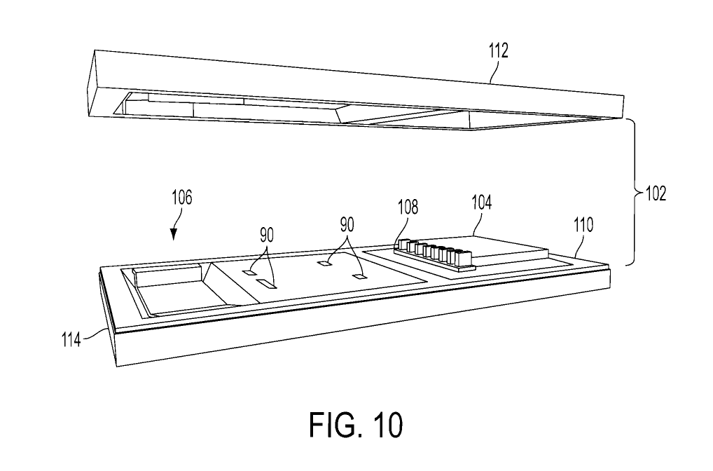

FIG. 10 shows an exploded view of the array 90 of FIG. 9 incorporated into a sensor device 102 where each of the four sensors includes a hydrogel in the cavity. An integrated circuit 104 can be operatively associated with the four sensors and configured to record changes in resistivity for each of the four sensors. An optional power source 106 (e.g. coil) can be operatively associated with the integrated circuit to provide electrical power to the circuit. Additional optional features can be further included for a particular design, e.g. surface mounted devices, wireless communications, encapsulation, processing, VLSI circuitry, wireless power supply (coil), telemetry, a Wheatstone bridge, and the like (shown generally at 108). A sealant 110 can be used to bond a complimentary cover 112 to the array casing 114 to form an integrated sensor device.

Such sensor arrays can be particularly useful as part of a chronically implantable microsensor array for monitoring biomarkers which are relevant to carbohydrate and fatty acid utilization. Such devices can be useful for decreasing lab testing costs, allow for home monitoring, and/or continuous monitoring, e.g. via remote signals. Additionally, sensors can include drug delivery devices where the membrane and piezoresistive elements can track and communicate the amount of drug delivered from the cavity as a drug diffuses out of the cavity.

Although sizes can vary for a particular application, the sensors of the present invention typically have a sensor size of about 0.5 mm to about 5 mm across, and typically from about 1 mm to about 3 mm. Two exemplary embodiments include a 1×1 mm square sensor and a 2×3 mm sensor.

These sensor designs provide for a diaphragm that not only flexes to allow measurement of deflection by piezoresistive elements, it also acts to allow chemical species to transit into and out of the cavity. By combining both of these functions on a common wall (e.g. the membrane), the expansion forces exerted by the reactive agent (e.g. hydrogel) are focused on the diaphragm rather than other walls of the cavity. In contrast, other such sensors have two flexible walls against which forces can expand. In the present invention, the common diaphragm and transit membrane allow for a significant improvement in sensitivity of the sensor.

The formed sensors and/or sensor arrays can be further prepared by encapsulation in suitable materials such as, but not limited to, Parylene, silicone, silicon carbide, and the like. For example, Parylene C at a thickness from about 3-4.5 μm can provide good performance. Optional surface treatments to improve biocompatibility can also be used to increase performance over long-term implantation applications and to sustain performance in light of fibrous encapsulation and exposure to plasma.

Incorporation of an array of permeation holes, particularly patterned ones, into the layer of first material can be used to produce areas with higher stress concentrations than if it was solid (assuming the same width and thickness). This allows for a higher sensitivity in using piezoresistive responsive features. Additionally, the size, shape, location, number, and pitch of the channels can be controlled to directly affect the allowance of movement from through the membrane, and thus access into and out of the cavity. This modification enables the manipulation of selectivity and response time when configured as a sensor. Further, the fabrication process is simplified, reducing the total manufacturing cost of the devices. The processes outlined herein also reduce the amount of work and time required to form a sensor.

These implantable micro-sensors also have the ability to take continuous physiological measurement data. These sensors can be fabricated using equipment conventionally used for the manufacture of microchips, a technology that for medical sensors lowers overall costs, improves performance, and reduces surgical invasiveness.

### EXAMPLES

The following example illustrates various methods of patterning holes in association with piezoresistive resistive features so as to increase sensitivity to the piezoresistive features, in accordance with the present invention. However, it is to be understood that the following are only exemplary or illustrative of the application of the principles of the present invention. Numerous modifications and alternative compositions, parameters, methods, and systems can be devised by those skilled in the art without departing from the spirit and scope of the present invention. The appended claims are intended to cover such modifications and arrangements. Thus, while the present invention has been described above with particularity, the following Examples provide further detail in connection with several specific embodiments of the invention.

### Example 1

Initial simulations of diaphragms with holes show proof of concept. Careful manipulation of hole parameters can alter the stress concentrations location with the diaphragm. Three quarter diaphragms were simulated having 550 μm in width with different hole patterns. The diaphragm was made of silicon with a 25 μm thickness and holes in each simulation were 25 μm with a 100 μm pitch. The sample 1 was a solid diaphragm with no holes. The sample 2 had a uniform distribution of holes throughout the membrane and the sample 3 had certain holes removed from the center of the diaphragm.

Table 1 summarizes the deflection and stress concentrations in the diaphragms at a load of 10⁵ Pa or ˜1 atm.

TABLE 1

| | Deflection | Max Stress (σ) | Max Stress |
|---|---|---|---|
| Geometry | (μm) | (MPa) | Location |
| No Holes | 0.18 | 6.3 | Midline Along the |
| | | | Edges |
| Uniform | 0.89 | 55 | Along Holes is |
| Holes | | | center of |
| | | | Diaphragm |
| Hybrid Holes | 0.38 | 29 | Stress shows to be |
| | | | a hybrid of the |
| | | | other locations. |

This simulation shows the manipulation of the holes location impacts the final stress distribution of where the piezoresistors would be located.

### Example 2

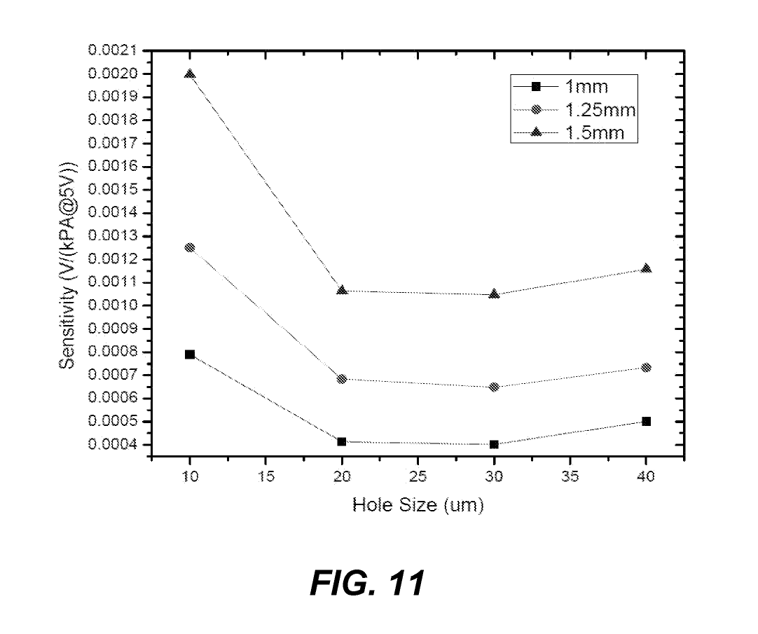

Actual membranes were formed with 50 μm spacing in a grid pattern. Each membrane was formed of silicon to a thickness of 15 μm. Three different membrane sizes of 1 mm, 1.25 mm and 1.5 mm in width were prepared with the same hole patterns. For each membrane size various hole sizes were also prepared, e.g. 10 μm, 20 μm, 30 μm and 40 μm. FIG. 11 is a graph of experimental results for sensitivity versus hole size for each membrane size. As can be seen, after reaching about 30 μm an increase in hole size results in an increase in sensitivity. This effect was also seen in comparable computer simulations.

It is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function, and manner of operation, assembly, and use may be made without departing from the principles and concepts set forth herein.

What is claimed is:

1. A sensor, comprising:
a cavity in a substantially rigid substrate;
a flexible machined membrane forming a wall of the cavity, the membrane including an array of machined channels configured to permit selective passage of a target material into and out of the cavity; and
at least one piezoresistive feature associated with the membrane to measure mechanical movement of the membrane.

2. The sensor of claim 1, wherein the cavity has a volume from about 0.01 mm³ to about 0.2 mm³.

3. The sensor of claim 1, wherein the membrane is attached to the substrate and the cavity is formed via front-side etching through the array of channels.

4. The sensor of claim 1, wherein the membrane and side walls of the cavity are formed of a single common piece and a bottom of the cavity is provided by a backing substrate.

5. The sensor of claim 4, wherein the solid substrate and flexible membrane are composed of materials which are biocompatible.

6. The sensor of claim 1, wherein the membrane comprises SiC and the substrate comprises Si.

7. The sensor of claim 1, wherein the membrane comprises a semiconducting material.

8. The sensor of claim 1, wherein the plurality of channels are in a non-random pattern.

9. The sensor of claim 1, wherein the plurality of channels are configured to function as a size-restrictive filter.

10. The sensor of claim 1, wherein the plurality of channels are located and spaced to increase sensitivity of the at least one piezoresistive responsive feature.

11. The sensor of claim 1, wherein the at least one piezoresistive feature is integrated into the flexible membrane.

12. The sensor of claim 1, wherein the at least one piezoresistive feature is fabricated onto the flexible membrane.

13. The sensor of claim 1, wherein the piezoresistive features are fabricated from at least one of germanium, polycrystalline silicon, amorphous silicon, silicon carbide, single crystal silicon diamond and piezoresistive semiconductor.

14. The sensor of claim 1, further comprising a reactive agent present in the cavity said reactive agent being volumetrically responsive to a presence of the target material.

15. The sensor of claim 14, wherein the reactive agent substantially fills the cavity and is configured to produce a force against the flexible membrane upon the presence of the target chemical having a specified wavelength.

16. The sensor of claim 15, wherein the reactive agent is a hydrogel which is volumetrically responsive to absorption of the target material.

17. The sensor of claim 16, wherein the hydrogel is selected from the group consisting of substituted acrylic or acrylamide copolymers, acrylic or acrylamide copolymers, PVA/PAA, NIPAAm copolymers, and combinations thereof.

18. The sensor of claim 16, wherein the hydrogel and the membrane are configured to be selectively permeable to at least one of glucose, CO₂, and hydrogen ion (pH detection).

19. The sensor of claim 18, wherein the membrane is part of a Severinghaus membrane for CO₂ detection.

20. The sensor of claim 1, wherein the target material is glucose.

21. The sensor of claim 1, wherein the membrane has four edges and the piezoresistive system comprises four piezoresistive elements, each oriented along one of the four edges.

22. The sensor array of claim 21, wherein the four sensors are each configured to detect glucose, CO₂, pH, and reference, respectively.

23. The sensor array of claim 21, further comprising:
an integrated circuit operatively associated with the four sensors and configured to record changes in resistivity for each of the four sensors; and
a Wheatstone bridge electrically associated between the piezoresistive system and the integrated circuit.
